(19) United States
(12) Patent Application Publication
(10) Pub. No.: US 2009/0108417 A1
(43) Pub. Date: Apr. 30, 2009

(54) Method and System for Providing a Continuous Impedance Along a Signal Trace in an IC Package

(75) Inventor: Chikara Azuma, Ushiku (JP)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 11/931,284

(22) Filed: Oct. 31, 2007

(51) Int. Cl. H01L 23/528; H01L 21/4763

(52) U.S. Cl. 257/664; 438/619; 257/E23.151; 257/E21.495

(57) ABSTRACT

A multi-layered integrated circuit chip package comprises a void layer that includes at least one void. The multi-layered integrated circuit chip package also includes an insulation layer that electrically insulates the void layer from a trace layer. At least one trace resides in the trace layer. The trace having a length in which a first section thereof is located an overlying relation to the at least one void, wherein the first section overlying the void has a width different from an adjacent section of the trace located on at least one opposing side of the void such that impedance mismatches and signal reflections along the trace are mitigated.

### TECHNICAL FIELD

This invention relates to integrated circuits, and more specifically, to systems and methods for providing continuous impedance along a signal trace.

### BACKGROUND

In the manufacture of integrated circuit chip packages, after individual devices (e.g., chips or dies) have been fabricated in and on a semiconductor substrate, the individual chips are assembled and packaged into a final IC package. One part of the fabrication process includes metallization, which is the deposition of a thin film of conductive metal onto a wafer by use of a chemical or physical process. Interlayer dielectrics are used to electrically separate the metal levels or layers in an IC. Metal lines or traces are formed to conduct signals through the IC while the dielectric layers help ensure that signals are not influenced by adjacent lines.

As one example, voids can be formed in one or more dielectric layers such as by etching. Voids can also be formed through the use of other metallization processes. The voids can be used to form part of a power or ground path of a multilayer IC package. In certain circumstances, voids may be unintended consequences of the packaging fabrication process, which voids can be referred to as split planes. Voids can adversely affect signals propagating along traces in the IC package especially at higher frequencies.

### SUMMARY

One aspect of the invention is related to a multi-layered integrated circuit chip package that comprises a void layer that includes at least one void. The multi-layered integrated circuit chip package also includes an insulation layer that electrically insulates the void layer from a trace layer. At least one trace resides in the trace layer. The trace having a length in which a first section thereof is located an overlying relation to the at least one void, wherein the first section overlying the void has a width different from an adjacent section of the trace located on at least one opposing side of the void such that impedance mismatches and signal reflections along the trace are mitigated.

Another aspect of the invention is related to a multi-layered integrated circuit chip package that includes a base layer for providing an external interface for the integrated circuit chip package. A void layer includes at least one interlayer connection and at least one void. A first dielectric layer resides between and electrically insulates the base layer and the void layer. A second dielectric layer resides between and electrically insulates the void layer from the trace layer. A trace layer comprises at least one elongated trace, at least one section of the trace overlying the at least one void. The at least one section of the trace has a first width that is greater than a second width of an adjacent section of the trace on at least one opposing side of the void as to provide a substantially constant impedance along the trace.

Still another aspect of the invention is related to a method for forming a multi-layered integrated circuit chip package. The method includes forming a void layer that includes at least one void therein. A dielectric layer is formed on the void layer that insulates the void layer. A trace layer is formed on the dielectric layer such that the dielectric layer insulates the void layer from the trace layer. At least one trace is formed in the trace layer, at least one section of a given trace overlying the at least one void. The at least one section of the given trace has a first width that is greater than a second width of an adjacent section of the trace that extends from the at least one section of the given trace laterally relative to the at least one void such that a substantially constant impedance across the trace.

### BRIEF DESCRIPTION OF THE DRAWINGS

FIG. 1 illustrates a top view of a portion of an integrated circuit chip package in accordance with an aspect of the invention.

FIG. 2 illustrates a cross sectional view of a portion of an integrated circuit chip package in accordance with an aspect of the invention.

FIG. 3 illustrates a graph of square waves transmitted across a signal trace in accordance with an aspect of the invention.

FIG. 4 is a graph illustrating attenuation in a transmission signal frequency response for a trace in an IC implemented in accordance with an aspect of the invention.

FIG. 5 is a graph illustrating attenuation in a reflection signal frequency response for a trace in an IC implemented in accordance with an aspect of the invention.

FIG. 6 illustrates another example of a top view of a portion of an integrated circuit chip package in accordance with an aspect of the invention.

FIG. 7 illustrates a flow-chart diagram of a process in accordance with an aspect of the invention.

### DETAILED DESCRIPTION

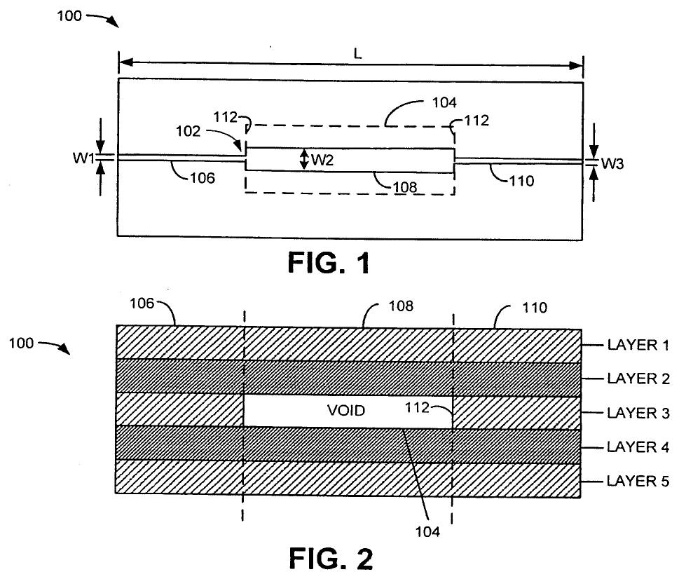

FIGS. 1 and 2 illustrate a respective top view and cross sectional views of a portion of an integrated circuit chip package 100 in accordance with an aspect of the invention. For purposes of simplification of explanation, the same reference numbers are used in FIGS. 1 and 2 when referring to the same features. In the present example, the illustrated integrated circuit chip package 100 includes five layers (LAYERS 1-5), although one skilled in the art will appreciate that more or less layers can be included. The LAYERS 1-5 could be formed, for example, in an integrated circuit (IC) fabrication process, such as including, lithography, deposition, etching and/or a packaging process, such as metallization. As an example, the top layer, LAYER 1 could be implemented as a layer of a metal material, such as copper or gold, which includes at least one signal trace 102. In the present example, the signal trace 102 transcribes the entire length (indicated at L) of the illustrated portion of the integrated circuit chip package 100, but one skilled in the art would appreciate that the signal trace 102 could be shorter. As an example, L could be about 18 millimeters (mm) or any other length depending on size of the IC and the circuit design. The next topmost layer, LAYER 2, can be implemented as a layer of dielectric material (e.g., an insulator).

The third topmost layer, LAYER 3 can be implemented as a metal layer, similar to LAYER 1, but wherein at least one material void 104 or split plane (hereinafter, “void”) is included. The void 104 can be formed, for example, as a result of the lithography and/or packaging techniques used to form the layers of the integrated circuit chip package 100. Although it is to be understood that LAYER 3 could include multiple voids, for purposes of simplification of explanation, only one void 104 is shown and described. The next layer, LAYER 4, can be implemented in a similar manner to LAYER 2, such that LAYER 4 also includes dielectric material. The lowermost layer, LAYER 5 could be implemented to include, for example, another signal trace, such as an interface pin that can connect the integrated circuit chip package 100 to external circuits. Additionally or alternatively, LAYER 5 could be implemented as including an electrically neutral (e.g., ground) plane, such as coupled with a grounding pin.

A characteristic impedance (Z₀), measured in ohms at any given point of the signal trace 102 can be estimated by the following equation:

$${Z}_{o} = \sqrt{\frac{L}{C}} \qquad Equation 1$$

where: L=the inductance (in Henries) per unit of length of the signal trace 102 at a given point on the signal trace 102; and

C=the capacitance (e.g., the parasitic capacitance) (in Farads) per unit of length of the signal trace 102 at the given point in the signal trace 102.

The characteristic impedance (Z₀) at the given point in the signal trace 102 can be affected by a variety of different factors. For instance, the inductance at the given point can vary inversely to the distance between the signal trace 102 at the given point and the closest material that can carry a current, such as another signal trace, or a ground. Additionally, the capacitance (e.g., the parasitic capacitance) of the signal trace 102 at the given point is proportionate to the width of the signal trace 102. Accordingly, varying the distance between the signal trace 102 at the given point and the closest material that can carry a current or varying the width of the signal trace 102 can vary the characteristic impedance (Z₀).

The signal trace 102 corresponds to a length of an electrically conductive material formed (e.g., via metallization) on a layer of the IC package. The trace may be substantially straight, curved or include a combination of straight and curved sections in a corresponding path along the IC. As described herein, the signal trace 102 has a length or longitudinal dimension and a width dimension, which width is measured transverse to its length or longitudinal dimension. Typically, the length dimension and the width dimension lie in substantially the same plane, although minor deviations from a plane may exist along the length of the trace.

In the present example of FIG. 1, the signal trace 102 can be considered to include three different sections, indicated at 106, 108 and 110. Two of the sections, 106 and 110, can correspond to the sections of the signal trace 102 overlying portions of LAYER 3 that include at least at one other signal trace (e.g., a via). A middle section 108 can correspond to a portion of the signal trace 102 that overlies at least a substantial portion of the void 104 in LAYER 3 (FIG. 2). The middle section has a length that is substantially coextensive with the distance between opposing side edges 112 of the void 104. At section 108 of the signal trace, due to the void 104, the closest layer to the signal trace 102 that can carry current changes from LAYER 3 to LAYER 5, thereby increasing the distance between the signal trace 102 and the closest material to the signal trace 102 that can carry a current. Thusly, the inductance at the intersection of sections 108 and 106 and at the intersection of sections 108 and 110 of the signal trace 102 is increased relative to the inductance along sections 106 and 110. To compensate for the increased inductance, the width of the signal trace 102 at 108 can be increased relative to the width of the signal trace 102 at sections 106 and 110.

In the present example, sections 106 and 110 of the signal trace 102 have a specific width, indicated at W1 and W3. It is to be understood that W1 and W3 could be different widths, but for purposes of simplification of explanation, W1 and W3 are considered to be substantially equal in the present example. As one example of a typical integrated circuit, the respective widths W1 and W3 could remain constant, such as about 35 micrometers (“μm”). In such an example, the characteristic impedance (Z₀) along sections 106 and 110 of the signal trace 102 can be, for example, about 54 ohms.

At section 108, the width of the signal trace 102, indicated at W2, can be selected based on, for example, the characteristic impedance (Z₀) along sections 106 and 110, the distance between LAYERS 1 and 3 relative to the distance between LAYERS 1 and 5, as well as the frequency of the signal provided on the signal trace 102. The width W2 of the section 108 can be substantially constant over the void, such as depicted in FIG. 1. W2 can be chosen, for example, to provide relatively continuous characteristic impedance (Z₀) across the entire length L of the signal trace 102, including along the section of the trace 108 overlying the void. For instance, W2 could be selected to be between about 50 μm and about 250 μm.

As stated above, if W1 and W3 are provided at about 35 μm, the characteristic impedance (Z₀) along sections 106 and 110 of the signal trace 102 can be, for example, about 54 ohms. In such an example, if W2 is selected to be about 50 μm, the characteristic impedance (Z₀) along section 108 of the signal trace 102 can be about 88 ohms. If W2 is increased to a width of about 80 μm, the characteristic impedance (Z₀) along section 108 of the signal trace 102 can be about 77 ohms. In another example, if W2 is increased to a width of about 120 μm, the characteristic impedance (Z₀) along section 108 of the signal trace 102 can be about 68 ohms. In yet another example, if W2 is increased to a width of about 150 μm, the characteristic impedance (Z₀) along section 108 of the signal trace 102 can be about 62 ohms. In still another example, if W2 is increased to a width of about 250 μm, the characteristic impedance (Z₀) along section 108 of the signal trace 102 can approximate 54 ohms corresponding to the impedance at sections 106 and 110. Providing substantially continuous characteristic impedance across the length L of the signal trace 102 reduces and/or eliminates impedance mismatching that causes signal reflections of alternating current (AC) signals propagating along the signal trace 102.

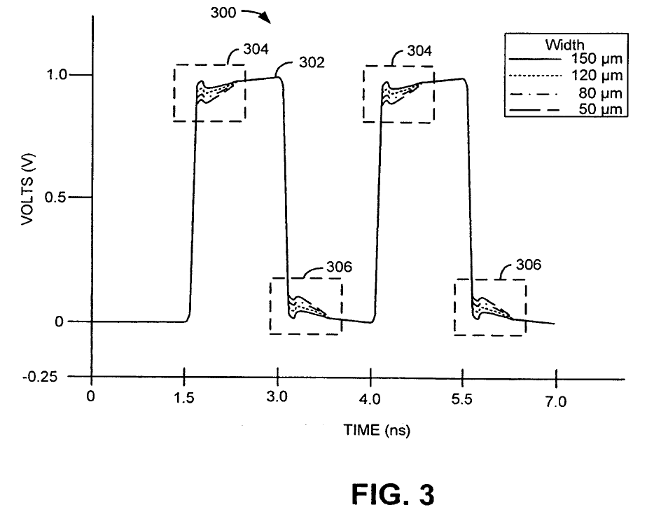

FIG. 3 illustrates a graph 300 of square waves 302 provided on a signal trace of an integrated circuit chip (e.g., the signal trace 102 illustrated in FIGS. 1 and 2) in accordance with an aspect of the invention. In FIG. 3, voltage, in volts (V) of the square wave signal is plotted as a function of time, in nanoseconds (ns). The square waves 302 can be provided, for example, at a frequency of about 2.66 megahertz (MHz). In FIG. 3, the graph includes plots for signals propagating in a signal trace having four different widths (50 μm, 80 μm, 120 μm and 150 μm) in a section overlying a void (e.g., W2 illustrated in FIG. 2). The adjacent contiguous sections of the signal trace have smaller widths (e.g., about 35 μm) relative to the each of the trace widths for the section overlying the void. As shown in FIG. 3, each width results in a different square wave 302 due to corresponding impedance changes. It is to be understood that some of the performance characteristics of the square waves 302 have been exaggerated for purposes of simplification of explanation.

The rising corners of the square waves 302, indicated at 304, as well as the falling corners of the square waves 302, indicated at 306, are substantially affected by the signal trace section width. As demonstrated in FIG. 3, increasing the width of the signal trace section overlying the void improves the form of the rising and falling corners 304 and 306 of the square waves 302. It is to be appreciated that the improvements to the form of rising and falling corners 304 and 306 of the square waves 302 can be attained (empirically) until the width of the section of the signal trace is such that the signal trace has substantially constant characteristic impedance over the length of the signal trace.

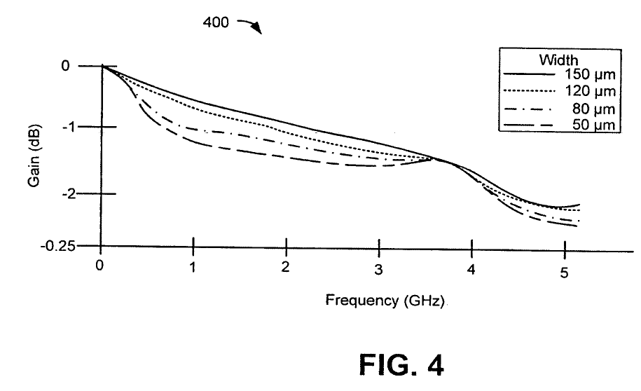

FIG. 4 illustrates a graph 400 of frequency responses of transmission signal attenuations for signals provided on a signal trace of an integrated circuit chip package (e.g., the signal trace 102 illustrated in FIGS. 1 and 2) in accordance with an aspect of the invention. In FIG. 4, transmission signal attenuation (or negative gain) of signal trace sections, in decibels (dB) is plotted as a function of frequency. In FIG. 4, the frequency response for transmission signal attenuation for four different widths (50 μm, 100 μm, 120 μm and 150 μm) of a section of the signal trace overlying a void is illustrated, where adjacent sections of such signal trace have respectively smaller widths. It is to be understood that some of the performance characteristics of the transmission signal attenuations have been exaggerated to help demonstrate the benefits of the approach and for purposes of simplification of explanation.

In one example, if the width is selected to be about 50 μm, the transmission signal attenuation increases from about 0 dB (e.g., unity) to about 1.25 dB at about 1 GHz. The transmission signal attenuation at 50 μm increases to about 1.4 dB from about 1 GHz to about 3 GHz. The transmission signal attenuation (at 50 μm) increases to about 1.5 dB between about 3 GHz and about 4 GHz, and increases to about 2.5 dB between about 4 GHz and about 5 GHz.

In another example, if the width is selected to be about 80 μm, the transmission signal attenuation increases from about 0 dB (e.g., unity) to about 1 dB at about 1 GHz. The transmission signal attenuation at 80 μm increases to about 1.25 dB from about 1 GHz to about 4 GHz. The transmission signal attenuation (at 80 μm) increases to about 2.5 dB between about 4 GHz and about 5 GHz.

In yet another example, if the width is selected to be about 120 μm, the transmission signal attenuation increases from about 0 dB (e.g., unity) to about 0.75 dB at about 1 GHz. The transmission signal attenuation at 120 μm increases to about 1.5 dB from about 1 GHz to about 4 GHz. The attenuation (at 120 μm) increases to about 2.25 dB between about 4 GHz and about 5 GHz.

In still yet another example, if the width is selected to be about 150 μm, the transmission signal attenuation increases from about 0 dB (e.g., unity) to about 0.75 dB at about 1 GHz. The transmission signal attenuation at 150 μm increases to about 1.5 dB from about 1 GHz to about 4 GHz. The attenuation (at 150 μm) increases to about 2.25 dB between about 4 GHz and about 5 GHz. As is illustrated in FIG. 4, increasing the width of the signal trace overlying the void decreases the transmission signal attenuation for a signal trace. It is to be appreciated that the width of the section of the signal trace overlying the void can be increased, thereby decreasing transmission signal attenuation until the trace section has a width providing for substantially constant characteristic impedance across the length of the signal trace. In most applications, smaller transmission signal attenuation is desirable; however, some applications (e.g., voltage regulation) can require a transmission signal attenuation of a certain gain.

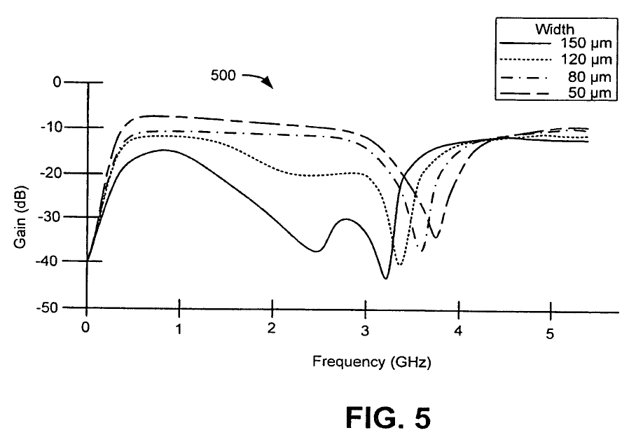

FIG. 5 illustrates a graph 500 of a frequency response for reflection signal attenuation for signals provided on a signal trace of a multilayer IC package (e.g., the signal trace illustrated in FIGS. 1 and 2) in accordance with an aspect of the invention. In FIG. 5, reflection signal attenuation (or negative gain) of a signal trace, in dB is plotted as a function of frequency in GHz. In FIG. 5, the frequency response for reflection signal attenuation for four different widths (50 μm, 80 μm, 120 μm and 150 μm) of a section of the signal trace is illustrated. Moreover, the four different widths (50 μm, 80 μm, 120 μm and 150 μm) can correspond, for example, to the width of a signal trace overlying a void (e.g., W2 illustrated in FIG. 2). It is to be understood that some of the performance characteristics of the reflection signal attenuations have been exaggerated for purposes of simplification of explanation.

In one example, if the width is selected to be about 50 μm, the reflection signal attenuation decreases from about 40 dB to about 8 dB at about 1 GHz. The reflection signal attenuation at 50 μm increases from about 8 dB to about 11 dB from about 1 GHz to about 3 GHz. The attenuation (at 50 μm) increases to about 32 dB between about 3 GHz and about 3.8 GHz, and decreases to about 9 dB between about 4 GHz and about 5 GHz.

In another example, if the width is selected to be about 80 μm, the reflection signal attenuation decreases from about 40 dB to about 11 dB at about 1 GHz. The reflection signal attenuation at 80 μm increases from about 11 dB to about 12 dB from about 1 GHz to about 3 GHz. The attenuation (at 80 μm) increases to about 35 dB between about 3 GHz and about 3.6 GHz, and decreases to about 10 dB between about 3.6 GHz and about 5 GHz.

In yet another example, if the width is selected to be about 120 μm, the reflection signal attenuation decreases from about 40 dB to about 13 dB at about 1 GHz. The reflection signal attenuation at 120 μm increases from about 13 dB to about 18 dB from about 1 GHz to about 3 GHz. The attenuation (at 120 μm) increases to about 38 dB between about 3 GHz and about 3.4 GHz, and decreases to about 12 dB between about 4 GHz and about 5 GHz.

In still another example, if the width is selected to be about 150 μm, the reflection signal attenuation decreases from about 40 dB to about 15 dB at about 1 GHz. The reflection signal attenuation at 120 μm increases from about 15 dB to about 38 dB from about 1 GHz to about 2.5 GHz. The reflection signal attenuation at 120 μm decreases from about 38 dB to about 30 dB from about 2.5 GHz to about 3 GHz. The attenuation (at 120 μm) increases to about 42 dB between about 3 GHz and about 3.25 GHz, and decreases to about 10 dB between about 4 GHz and about 5 GHz. As is illustrated in FIG. 5, increasing the width of the section of the signal trace overlying a void increases the reflection signal attenuation for a signal trace. It is to be appreciated that the width of the section of the signal trace overlying a void can be increased, thereby increasing the reflection signal attenuation, until the signal trace has substantially constant characteristic impedance across its length. In most applications, increased reflection signal attenuation is desirable; however, some applications (e.g., voltage regulation) can require a reflection signal attenuation of a certain gain. Accordingly, certain applications may require a balancing of the attenuation of signal transmission, signal reflection and trace width to achieve desired operating parameters.

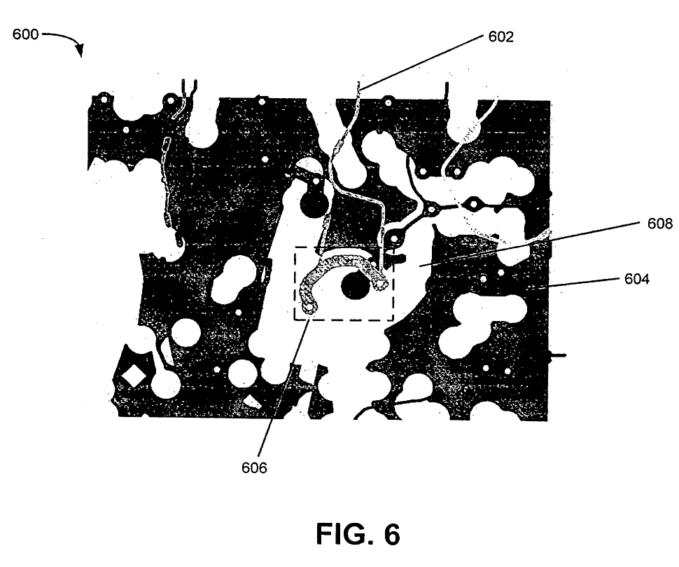

FIG. 6 illustrates an example of a portion of a multi-layered integrated circuit chip package 600 (e.g., a stacked die package) in accordance with an aspect of the invention. The multi-layered integrated circuit chip 600 can have, for example, a signal trace 602 that can transmit high frequency signals, (e.g., signals of 1 MHz or greater). The signal trace 602 can include sections overlying a ground plane 604 or another signal trace, such as a via. At the sections of the signal trace 602 overlying the ground plane 604 or another signal trace, the signal trace 602 can have a width, for example, of about 35 μm. The sections of the signal trace 602 overlying the ground plane 604 or another signal trace can have a characteristic impedance of about 54 ohms.

The signal trace 602 can also include, a section, indicated at 606 overlying a void 608. The section 606 of the signal trace 602 can be provided with a width that is substantially wider (e.g., between about 50 μm and about 250 μm) than the width of the signal trace 602 over the ground plane 604 or another signal trace (e.g., about 35 μm) to compensate for an increase in inductance associated with the potion of the signal trace 602 overlying the void 608. Such a substantially greater trace width increases the capacitance of the signal trace 602 for the corresponding section 606 of the signal trace 602. As is shown, the section 606 can have a curved shape. One skilled in the art will appreciate the other shapes of the section 606 that are possible, such as may vary according to the particular routing an layout in a give circuit design. Increasing the capacitance compensates for the increased inductance to reduce and/or eliminate impedance mismatching that can occur along the length of the signal trace 602.

As discussed in the above examples, the sections of the signal trace 602 overlying the ground plane 604 or another signal trace can be selected to have a nominal width, for example about 35 μm. In this example, it is assumed that portions of the trace having nominal trace width (e.g., about 35 μm) have a characteristic impedance of about 54 ohms. The width of the section 606 of the signal trace 602 overlying the void 608 has a different characteristic impedance from the adjacent sections of the signal trace 602 that varies depending on the width of such section relative to the width of the adjacent sections. Accordingly, the width of the section 606 can be constructed to have a width that is greater than the width of adjacent sections of the signal trace 602 (which do not overly a void) to provide a substantially uniform characteristic impedance along the length of the signal trace. Providing relatively uniform characteristic impedance across the length the signal trace 602 reduces impedance mismatches that can cause signal reflections of high frequency AC signals propagating along the signal trace 602. One skilled in the art will appreciate that the importance of the signal trace 602 width for given IC is dependent upon the frequency of the signals provided on the signal trace 602, the size of the void 608, and other design considerations described herein.

By way of example, if the width of the section 606 of the signal trace 602 overlying the void 608 is selected to be about 50 μm, such section 606 overlying the void 608 can have a characteristic impedance of about 88 ohms. Moreover, if the width of the section 606 of the signal trace 602 overlying the void 608 is selected to be about 80 μm, the section 606 overlying the void 608 can have a characteristic impedance of about 77 ohms. If the width of the section 606 of the signal trace 602 overlying the void 608 is selected to be about 120 μm, the section 606 overlying the void 608 can have a characteristic impedance of about 68 ohms. If the width of the section 606 of the signal trace 602 overlying the void 608 is selected to be about 150 μm, the section 606 overlying the void 608 can have a characteristic, impedance of about 62 ohms. If the width of the section 606 of the signal trace 602 overlying the void 608 is selected to be about 250 μm, the section 606 overlying the void 608 can have a characteristic impedance of about 54 ohms.

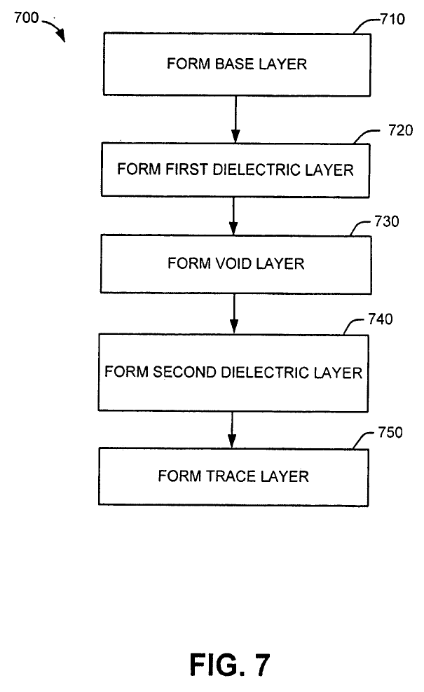

FIG. 7 illustrates an example of a basic and simplified process 700 that can be used to form an integrated circuit chip package in accordance with an aspect of the invention. The process 700 can be performed by a number of different semiconductor fabrication and/or packaging techniques that are known. The techniques could also include, for example, metallization, such as by employing a sputter technique and patterning. One skilled in the art will appreciate that other techniques can be employed as well.

At 710, a base layer can be formed. The base layer can include, for example, a ground plane or other substrate of a suitable material. The ground plane can provide, for example, an interface for the integrated circuit chip to external circuitry. At 720, a first dielectric layer can be formed. The first dielectric layer can include insulation material to insulate the base layer from other layers of the integrated circuit chip. At 730, a void layer can be formed. The void layer can include, for example, one or more signal traces, such as inter-layer connectors (e.g., vias) that can extend through the void layer between a top surface and a bottom surface thereof. The signal traces in the void layer can be formed from a metal, such as copper. The copper can be deposited, for example, in etched channels. However, copper in the channels tends to shrink since the thermal coefficient of copper is higher than the thermal coefficient of dielectric layers (such as the first dielectric layer). Due to the copper's shrinkage, voids can form in the copper in different areas, but often form at or near the inter-layer connectors (e.g., vias). Accordingly, the void layer can include one or more voids within the void layer.

At 740, a second dielectric layer can be formed. The second dielectric layer can include insulation material to insulate the void layer from other layers of the integrated circuit chip. At 750 a trace layer can be formed. The trace layer can include, for example, at least one signal trace. The signal trace can be formed such that at least a portion of the signal trace overlies a portion of the void in the void layer. The signal trace can be formed such that it includes at least two contiguous sections having different widths, where the section having the greater width overlies a void. For instance, the signal trace can have a width of about 35 μm at section(s) of the signal trace that do not overlie the void. Additionally, the signal trace can have a width of about 50 μm to about 250 μm along the portion(s) of the signal trace overlying the void. The width of the signal trace along the portion of the signal trace overlying the void can be selected, for example, based on the frequency of signals provided at the signal trace, as well as the physical size of the void. Increasing the width of the signal trace along the portion of the signal trace overlying the void can reduce and/or eliminate impedance mismatching that would otherwise be caused by the void.

What have been described above are examples of the invention. It is, of course, not possible to describe every conceivable combination of components or methodologies for purposes of describing the invention, but one of ordinary skill in the art will recognize that many further combinations and permutations of the invention are possible. Accordingly, the invention is intended to embrace all such applications including alterations, modifications and variations that fall within the scope of the appended claims.

What is claimed is:

1. A multi-layered integrated circuit chip package comprising:
a void layer that includes at least one void;
an insulation layer that electrically insulates the void layer from a trace layer; and
at least one trace residing in the trace layer, the at least one trace having a length in which a first section thereof is located an overlying relation to the at least one void, wherein the first section overlying the at least one void has a width different from an adjacent section of the at least one trace located on at least one opposing side of the at least one void such that impedance mismatches and signal reflections along the at least one trace are mitigated.

2. The multi-layered integrated circuit chip package of claim 1, wherein the insulation layer is a first insulation layer, the multi-layered integrated circuit chip package further comprising:
a base layer that includes a relatively electrically neutral conduction structure; and
a second insulation layer that electrically insulates the base layer from the void layer.

3. The multi-layered integrated circuit chip package of claim 1, wherein the at least one trace includes at least one curved section.

4. The multi-layered integrated circuit chip package of claim 1, wherein the width of first section of the at least one trace overlying the at least one void is greater than the width of the adjacent section of the at least one trace on the at least one opposing side of the at least one void.

5. The multi-layered integrated circuit chip package of claim 4, wherein the first section of the at least one trace overlying the at least one void has a substantially constant width that is greater than the width of adjacent sections of the at least one trace on opposing sides of the at least one void.

6. The multi-layered integrated circuit chip package of claim 1, wherein the first section of the at least one trace overlying the at least one void has a length that approximates a distance between opposing side edges of the at least one void over which the first section of the at least one trace extends.

7. The multi-layered integrated circuit chip package of claim 1, wherein the width of the first section of the at least one trace overlying the at least one void is in a range from about 50 micrometers to about 250 micrometers, and the width of the at least one trace on the at least one opposing side of the at least one void is less than or equal to about 35 micrometers.

8. A multi-layered integrated circuit chip package comprising:
a base layer for providing an external interface for the multi-layered integrated circuit chip package;
a void layer that includes at least one interlayer connection and at least one void;
a first dielectric layer that resides between and electrically insulates the base layer and the void layer;
a second dielectric layer that resides between and electrically insulates the void layer from a trace layer; and
the trace layer that comprises at least one elongated trace, at least one section of the elongated trace overlying the at least one void, the at least one section of the elongated trace having a first width that is greater than a second width of an adjacent section of the elongated trace on at least one opposing side of the at least one void as to provide a substantially constant characteristic impedance along the elongated trace.

9. The multi-layered integrated circuit chip package of claim 8, wherein the first width is at least about 1.5 times the second width.

10. The multi-layered integrated circuit chip package of claim 8, wherein the second width is less than or equal to about 35 micrometers.

11. The multi-layered integrated circuit chip package of claim 10, wherein the first width is at least about 80 micrometers.

12. The multi-layered integrated circuit chip package of claim 8, wherein each of the at least one section of the elongated trace has a substantially constant width that is greater than the second width.

13. The multi-layered integrated circuit chip package of claim 12, wherein each of the at least one section of the elongated trace overlying the at least one void has a length that approximates a distance between opposing side edges of the at least one void over which each at least one section of the elongated trace extends.

14. A method for forming a multi-layered integrated circuit chip package, the method comprising:
forming a void layer that includes at least one void therein;
forming a dielectric layer on the void layer that insulates the void layer;
forming a trace layer on the dielectric layer; and
forming at least one trace at the trace layer, at least one section of a given trace overlying the at least one void, wherein the at least one section of the given trace has a first width that is greater than a second width of an adjacent section of the given trace that extends from the at least one section of the given trace relative to the at least one void such that a substantially constant impedance across the given trace.

15. The method of claim 14, wherein the dielectric layer is a first dielectric layer, the method further comprising:
forming a base layer that includes at least one other trace;
forming a second dielectric layer over the base layer, wherein the void layer is formed over the first dielectric layer.

16. The method of claim 14, wherein the first width is about 1.5 times greater than the second width.

17. The method of claim 14, wherein the first width is substantially constant along a length of the at least one section of the given trace overlying the at least one void.
